(19) United States
(12) Patent Application Publication
(10) Pub. No.: US 2023/0280554 A1
(43) Pub. Date: Sep. 7, 2023

(54) OPTO-ELECTRIC HYBRID BOARD, OPTICAL COMMUNICATION MODULE USING SAME, AND OPTICAL ELEMENT INSPECTION METHOD

(71) Applicant: NITTO DENKO CORPORATION, Ibaraki-shi, Osaka (JP)

(72) Inventors: Tadao Okawa, Ibaraki-shi (JP); Takashi Oda, Ibaraki-shi (JP); Masataka Yamaji, Ibaraki-shi (JP); Kazushi Ichikawa, Ibaraki-shi (JP)

(73) Assignee: NITTO DENKO CORPORATION, Ibaraki-shi, Osaka (JP)

(21) Appl. No.: 18/010,561

(22) PCT Filed: Jul. 2, 2021
(86) PCT No.: PCT/JP2021/025080

§ 371 Date: Dec. 15, 2022

(30) Foreign Application Priority Data
Jul. 13, 2020 (JP) 2020-119868

(51) Int. Cl. G02B 6/42; H05K 1/02

(52) U.S. Cl. CPC G02B 6/428; H05K 1/0274; G02B 6/4293

(57) ABSTRACT

An opto-electric hybrid board for an optical communication module in which an electric circuit part E including a pad for mounting an optical element, a pad for an optical element driving device, and an electrical interconnect line Y including an interconnect line portion A connecting the pads is provided on a first surface side of an insulative layer, and in which an optical waveguide W is on a second surface side of the insulative layer. A portion of a coverlay covering the electric circuit part E which overlaps the interconnect line portion A is removed to form an opening. The interconnect line portion A exposed through the opening is used as a terminal for a burn-in test of an optical element.

### TECHNICAL FIELD

The present disclosure relates to an opto-electric hybrid board, an optical communication module using the same, and an optical element inspection method for the optical communication module. More particularly, the present disclosure relates to a technique capable of easily inspecting an optical element mounted on the aforementioned optical communication module for initial failure to provide an optical communication module excellent in quality reliability.

### BACKGROUND ART

In recent electronic devices, optical interconnect lines have been used in addition to electrical interconnect lines with an increase in the amount of transmission information, and opto-electric hybrid boards in which the electrical and optical interconnect lines are compactly arranged have been prized. Also, the use of the aforementioned opto-electric hybrid boards for optical communication modules and the like which perform high-speed signal transmission by further connection to wiring boards and the like including a signal transmission function to various electronic devices has been expanding.

An example of such optical communication modules is schematically shown in FIG. 12. This optical communication module includes an opto-electric hybrid board 2 integrally connected to a wiring board 1. More specifically, multiple pairs of electrical interconnect lines X for differential signal transmission are provided on a surface of the wiring board 1.

The opto-electric hybrid board 2 includes an insulative layer 3 (indicated by cross-hatching in FIG. 12) having a wide portion and a narrow portion. An electric circuit part 6 including electrical interconnect lines Y, an optical element 4, and an optical element driving device (an IC or the like) 5 is provided on a backside surface of the wide portion of the insulative layer 3, i.e. on a surface to be overlaid on the surface of the wiring board 1. A portion of the electric circuit part 6 where insulation is required is covered with a coverlay.

On the other hand, a metal reinforcement layer 7 for reinforcing the electric circuit part 6 is provided on the opposite surface of the insulative layer 3 from the electric circuit part 6 (a front-side surface as seen in FIG. 12). An optical waveguide 8 is provided on the surface of the insulative layer 3 where this metal reinforcement layer 7 is provided so as to partially overlap the metal reinforcement layer 7. A reflecting surface for changing the path of light (not shown) is formed in a portion of the optical waveguide 8 which faces the optical element 4 across the insulative layer 3. Light reflected from the reflecting surface is optically coupled to the optical element 4. The metal reinforcement layer 7 is provided with a through hole 14 (with reference to FIG. 13) so as not to obstruct the path of light for the aforementioned optical coupling.

The electric circuit part 6 of the opto-electric hybrid board 2 will be described in further detail with reference to FIG. 13 which schematically shows this portion on an enlarged scale. Specifically, pads 10 for mounting the optical element 4 (indicated by dash-dot lines) and pads 11 for mounting the optical element driving device 5 (the IC or the like; indicated by dash-dot lines) for driving this optical element 4 are formed in the electric circuit part 6 provided on the one surface of the insulative layer 3. The electrical interconnect lines Y including interconnect line portions A for connecting the pads 10 and 11 extend to an end edge on the opposite side from where the optical waveguide 8 extends.

The electrical interconnect lines Y convert an optical signal into an electric signal and transmit the electric signal as a differential signal to the electrical interconnect lines X of the wiring board 1 (with reference to FIG. 12). Terminals 13 serving as connection points to the electrical interconnect lines X are provided at the tips of the electrical interconnect lines Y. Portions which require insulation, such as the electrical interconnect lines Y, except the pads 10 and 11 and the terminals 13 are covered by a coverlay 12 formed on this surface. In FIG. 13, a region in which the coverlay 12 is formed is indicated by diagonal lines extending from bottom left to top right.

There has been a growing need for transmitting an enormous amount of information including image information and audio information at higher speeds and with higher accuracy using such an optical communication module, and there has been a strong demand for even denser optical interconnect lines and higher frequencies of electric and optical signals. Also, once the aforementioned optical communication module is incorporated into electric and electronic equipment, it is often difficult to immediately repair or replace members even if a defect occurs during use. To solve such a problem, it has been proposed, for example, to conduct a burn-in test on optical elements to be mounted in the aforementioned optical communication module independently prior to the mounting, thereby previously eliminating those which might cause initial failure (see PTL 1, for example).

Further, it has been proposed to provide in the optical communication module an electric circuit capable of conducting the burn-in test on optical elements by switching, thereby inspecting the mounted optical elements for initial failure prior to actual use (see PTL 2, for example).

### RELATED ART DOCUMENTS

### Patent Documents

PTL 1: JP-A-2008-227463
PTL 2: JP-B-4645655

### SUMMARY

Unfortunately, the method of conducting the burn-in test on optical elements independently is not capable of detecting “initial failure” that causes a defect in the optical elements which are actually mounted on a board and optically coupled to an optical waveguide. For this reason, this method does not sufficiently ensure quality reliability as the optical communication module.

The technique in which the electric circuit for conducting the burn-in test on optical elements is provided in the optical communication module is preferable in being able to inspect the mounted optical elements for initial failure. However, the incorporation of the electric circuit for inspection which is irrelevant to the actual use gives rise to a problem such that the optical communication module is bulky and high in costs. In addition, such an optical communication module incorporating the electric circuit for the burn-in test is costly, which in turn makes the optical communication module difficult to adopt for consumer applications.

In view of the foregoing, the present disclosure provides: an opto-electric hybrid board which allows a burn-in test to be conducted reliably on an optical element mounted on a board with high accuracy, thereby providing an optical communication module excellent in quality reliability at low costs, although having a simple configuration adoptable for consumer applications; an optical communication module using the opto-electric hybrid board; and an optical element inspection method in the optical communication module.

The present disclosure provides the following [1] to [8].

[1] An opto-electric hybrid board for use in an optical communication module, comprising: an insulative layer; an electric circuit part provided on a first surface side of the insulative layer, the electric circuit part including a pad for mounting an optical element, a pad for an optical element driving device, and an electrical interconnect line Y including an interconnect line portion A connecting the pads; a coverlay covering the electric circuit part; and an optical waveguide provided on a second surface side of the insulative layer, wherein the coverlay has an opening in an area overlapping the interconnect line portion A, and the interconnect line portion A exposed through the opening is used as a terminal for a burn-in test of an optical element.

[2] The opto-electric hybrid board according to [1], wherein an opening dimension J of the opening of the coverlay as measured in a longitudinal direction of the interconnect line portion A is set to 0.5 to 1.2 when a longitudinal dimension H of the interconnect line portion A including the pads on opposite sides is 1.

[3] An optical communication module comprising: an opto-electric hybrid board as recited in [1] or [2]; and a wiring board electrically connected to the opto-electric hybrid board, wherein at least an optical element is mounted on the opto-electric hybrid board and is optically coupled to the optical waveguide of the opto-electric hybrid board, and wherein the interconnect line portion A exposed through the opening provided in the coverlay of the opto-electric hybrid board is used as a terminal for a burn-in test of the optical element.

[4] The optical communication module according to [3], the optical communication module being for consumer use.

[5] An optical element inspection method, wherein, in the step of obtaining an optical communication module as recited in [3] or [4], at least the optical element is mounted; a current is passed through the optical element with the use of the interconnect line portion A exposed through the opening of the coverlay as a terminal, with the optical element optically coupled to the optical waveguide of the opto-electric hybrid board; the current is converted into an optical signal by the optical element; the optical signal is outputted through the optical waveguide; and the outputted optical signal is measured, whereby the quality of the optical element is inspected.

[6] The optical element inspection method according to [5], wherein a current having a current value 1.5 to 3 times a current value for driving the optical element during actual use is passed through the optical element, whereby the inspection is conducted.

[7] An optical element inspection method, wherein, in the step of obtaining an optical communication module as recited in [3] or [4], at least the optical element is mounted; a reverse bias voltage is applied to the optical element with the use of the interconnect line portion A exposed through the opening of the coverlay as a terminal, with the optical element optically coupled to the optical waveguide of the opto-electric hybrid board; and a current generated in the optical element is measured, whereby the quality of the optical element is inspected.

[8] An optical element inspection method, wherein, in the step of obtaining an optical communication module as recited in [3] or [4], at least the optical element is mounted; an optical signal is transmitted through the optical waveguide to the optical element, with the optical element optically coupled to the optical waveguide of the opto-electric hybrid board; the optical signal is converted into an electric signal in the optical element; and the electric signal is measured with the use of the interconnect line portion A exposed through the opening of the coverlay as a terminal, whereby the quality of the optical element is inspected.

The present inventors have diligently made studies about a structure capable of easily and reliably conducting a burn-in test on a mounted optical element in an optical communication module. As a result, the present inventors have found that if an interconnect line portion connecting the optical element and an optical element driving device is not covered with a coverlay but is exposed through an opening, a probe pin for the burn-in test can be brought into electrical contact with the exposed interconnect line portion, whereby the burn-in test is conducted easily.

Although having a simple configuration such that only the opening is provided in a portion of the coverlay covering the electric circuit part, the opto-electric hybrid board of the present disclosure allows the burn-in test to be conducted reliably with high accuracy by causing a probe pin to conduct through this portion. The opto-electric hybrid board is not obtained by performing a special process but is obtained easily at low costs. This allows a wide use of the opto-electric hybrid board for consumer applications. Also, there is no need to incorporate an electric circuit for the burn-in test. This eliminates the need to provide extra space in the opto-electric hybrid board. Thus, the opto-electric hybrid board maintains a compact structure.

In addition, when the opening is provided in the coverlay covering the electric circuit part as mentioned above to expose the interconnect line portion connecting the optical element and the optical element driving device in the opto-electric hybrid board, the capacitance of the optical element is smaller than that obtained when the opening is not provided. This is advantageous in that the opto-electric hybrid board can be used in higher frequency bands. In general, the greater the effective capacitance of the optical element mounted on the opto-electric hybrid board is, the more a frequency band makes a transition to a lower frequency side than a higher frequency band that the optical element exhibits prior to the mounting. On the other hand, the provision of the opening as described above minimizes capacitance generated between interconnect lines which is added to the capacitance of the optical element itself, whereby the frequency band of the optical element prior to the mounting is maintained and a higher frequency signal is transmitted even after the mounting of the optical element.

Although low-cost and compact, the optical communication module of the present disclosure using the opto-electric hybrid board is easy to conduct the burn-in test on the optical element mounted thereon. Thus, the optical communication module is inspectable for initial failure and is excellent in quality reliability.

The optical element inspection method of the present disclosure is capable of conducting the burn-in test on the mounted optical element with a simple operation to check the optical element for initial failure, based on the optical and electrical properties thereof. This inspection is performed easily before the optical communication module is connected to an intended electric and electronic device and laid in a building or incorporated inside an apparatus. This provides the optical communication module excellent in quality reliability.

### BRIEF DESCRIPTION OF DRAWINGS

FIG. 1 is an illustration schematically showing a vertical section of principal parts of an opto-electric hybrid board according to one embodiment of the present disclosure.

FIG. 2 is an illustration schematically showing an electric circuit part formed in the aforementioned opto-electric hybrid board as seen from the side where the electric circuit part is formed.

FIG. 3 is an illustration of a manufacturing step of the aforementioned opto-electric hybrid board.

FIG. 4 is an illustration of a manufacturing step of the aforementioned opto-electric hybrid board.

FIG. 5 is an illustration of a manufacturing step of the aforementioned opto-electric hybrid board.

FIG. 6 is an illustration of a manufacturing step of the aforementioned opto-electric hybrid board and a manufacturing step of an optical communication module using the opto-electric hybrid board.

FIG. 7 is a schematic illustration illustrating a method of conducting a burn-in test in the aforementioned optical communication module as seen from the side where the electric circuit part of the opto-electric hybrid board is formed.

FIG. 8 is a schematic illustration illustrating the method of conducting the burn-in test with the use of a vertical section of the opto-electric hybrid board.

FIG. 9 is a schematic illustration illustrating another method of conducting the burn-in test with the use of a vertical section of the opto-electric hybrid board.

FIG. 10 is a schematic illustration illustrating still another method of conducting the burn-in test with the use of a vertical section of the opto-electric hybrid board.

FIGS. 11A and 11B are illustrations showing modifications of an opening of a coverlay in the aforementioned opto-electric hybrid board.

FIG. 12 is a schematic partial illustration showing an example of a general optical communication module.

FIG. 13 is a schematic illustration illustrating an electric circuit part in an opto-electric hybrid board for use in the aforementioned optical communication module.

### DESCRIPTION OF EMBODIMENTS

Next, an embodiment of the present disclosure will now be described in detail with reference to the drawings. However, the present disclosure is not limited to the following embodiment.

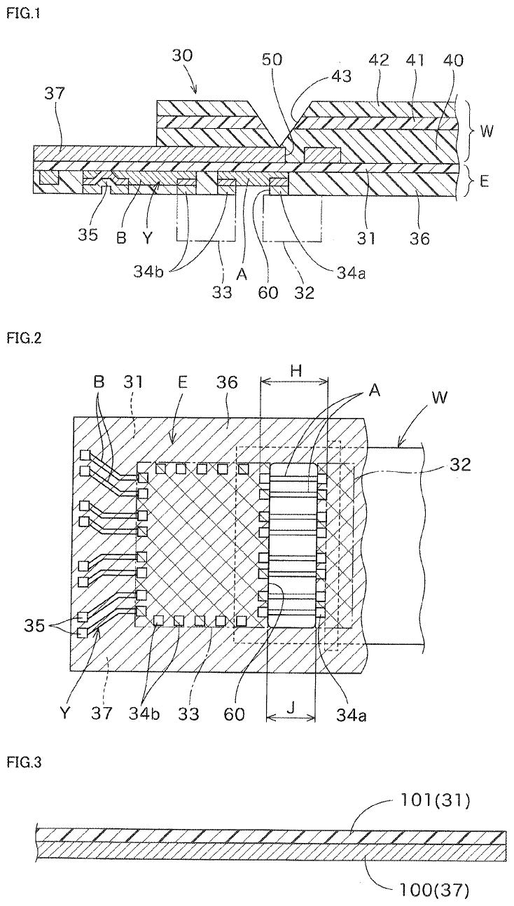

FIG. 1 is an illustration schematically showing principal parts of an opto-electric hybrid board according to one embodiment of the present disclosure taken in a direction of extension of an optical waveguide.

This opto-electric hybrid board 30 is used for an optical communication module, and is identical in basic configuration with general opto-electric hybrid boards. Specifically, a single insulative layer 31 of a substantially strip-shaped configuration serves as a substrate. An electric circuit part E is provided on one surface (a first surface) of the insulative layer 31. The electric circuit part E includes multiple pairs of electrical interconnect lines Y for transmitting a differential signal, pads 34a for mounting an optical element (a photodiode, a VCSEL, or the like) 32, pads 34b for mounting an optical element driving device (an IC or the like) 33, and the like (with reference to FIG. 2). A portion of the electric circuit part E where insulation protection is required is covered with a coverlay 36. It should be noted that the optical element 32 and the optical element driving device 33 are not attached in some cases in the stage of the opto-electric hybrid board, and are indicated by dash-dot lines.

The electric circuit part. E of the opto-electric hybrid board will be described in further detail. Specifically, the pads 34a for mounting the optical element 32 indicated by diagonal lines extending top left to bottom right and the pads 34b for mounting the optical element driving device 33 similarly indicated by diagonal lines extending top left to bottom right are provided in the electric circuit part E, as shown in FIG. 2 where the opto-electric hybrid board 30 is viewed from the side where the electric circuit part E is formed. Connecting terminals 35 for connecting the opto-electric hybrid board to a wiring board having the function of transmitting signals to various electronic devices are provided in an end portion of the electric circuit part E.

The electrical interconnect lines Y of the electric circuit part E include interconnect line portions A for connection between the pads 34a for the optical element 32 and the pads 34b for the optical element driving device 33, and interconnect line portions B for connection between the pads 34b and the connecting terminals 35 for other wiring boards. Of course, other interconnect lines are also formed as needed, but are not shown.

As mentioned earlier, the portion of the electric circuit part E where insulation protection is required is covered with the coverlay 36. The portion where insulation protection is required generally refers to all areas where the electrical interconnect lines Y are formed, excluding areas where energization is required, such as the pads 34a and 34b for mounting the optical element 32 and the like, and the connecting terminals 35. In the present disclosure, the coverlay 36 is not formed in an area overlapping the interconnect line portions A connecting the pads 34a for mounting the optical element 32 and the pads 34b for the optical element driving device 33, especially in the electrical interconnect lines Y. This area is a rectangular opening 60 that continuously spans the interconnect lines of the interconnect line portions A. This is a striking feature of the present disclosure. For clarity, a region where the coverlay 36 is formed is indicated by diagonal lines extending from bottom left to top right in FIG. 2.

On the other hand, a metal reinforcement layer 37 (with reference to FIG. 1) for reinforcing the strength of the insulative layer 31 is partially provided in a region where reinforcement is required on the other surface (a second surface) of the insulative layer 31, i.e. a surface on the opposite side from where the electric circuit part E is provided. An under cladding layer 40, a core 41, and an over cladding layer 42 are stacked in the order named in an arrangement that partially overlaps the metal reinforcement layer 37 on the other surface of the insulative layer 31. These three layers form an optical waveguide W. A portion of the optical waveguide W is cut into an inclined surface. The inclined surface serves as a light reflecting portion 43 for changing the direction of travel of an optical signal transmitted through the core 41 by 90 degrees. The metal reinforcement layer 37 is provided with a through hole 50 so as not to obstruct the path of light for optical coupling to the optical element 32 via the light reflecting portion 43.

<Steps of Forming Opto-Electric Hybrid Board>

Next, exemplary steps of obtaining the opto-electric hybrid board 30 will be briefly described while illustrating specific materials.

(1) Formation of Electric Circuit. Part E

First, as shown in FIG. 3, a metal plate 100 which becomes the metal reinforcement layer 37 is prepared, and a photosensitive insulating resin such as polyimide is applied to a surface of the metal plate 100 to form an insulating resin layer 101 which becomes the insulative layer 31.

Examples of the material of the metal plate 100 include stainless steel, copper, silver, aluminum, nickel, chromium, titanium, platinum, and gold. In particular, stainless steel is preferable from the viewpoint of strength, bendability, and the like. The metal reinforcement layer 37 has a thickness preferably in the range of 10 to 70 μm (more preferably in the range of 10 to 30 μm), for example.

Then, a photolithographic process (exposure, pre-bake, development, and cure) is performed on the insulating resin layer 101 to form the insulative layer 31 having a predetermined pattern shape. The insulative layer 31 has a thickness preferably in the range of 3 to 50 μm (more preferably in the range of 3 to 25 μm), for example (although this step is not shown).

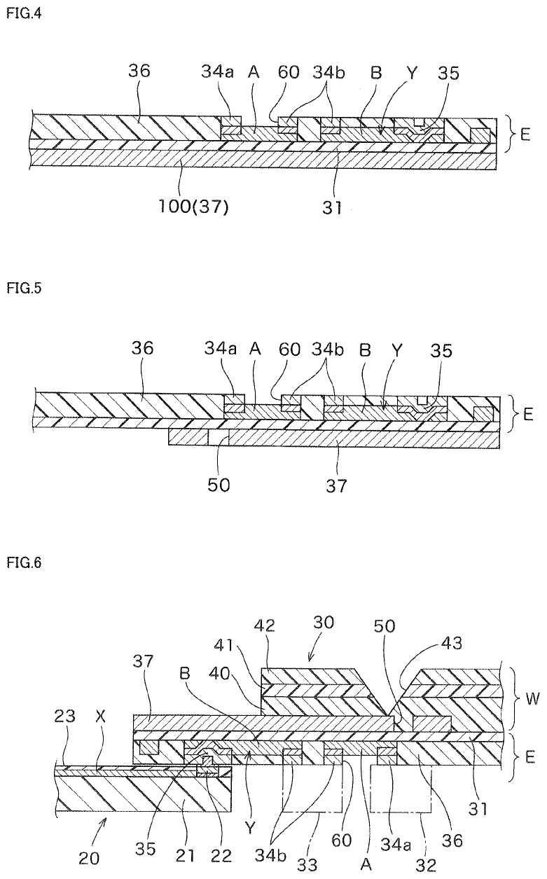

Next, an electrically conductive layer made of an electrically conductive material such as copper is formed on the insulative layer 31 by sputtering, electroless plating, or the like. Thereafter, necessary processes such as dry film resist lamination, exposure, and development are performed to form an electrically conductive pattern such as the electrical interconnect lines Y including the interconnect line portions A and B, the various pads 34a and 34b, and the connecting terminals 35. Then, as shown in FIG. 4, a photosensitive insulating resin such as polyimide is applied onto the electrically conductive pattern, and the same process as the formation of the insulative layer 31 is performed, whereby the coverlay 36 is formed in the area where insulation protection is required. At this time, an opening for exposing the pads 34a and the like and the opening 60 (with reference to FIG. 2) for exposing the interconnect line portions A are provided in the coverlay 36.

Metallic materials excellent in electrical conductivity and ductility such as chromium, aluminum, gold, and tantalum in addition to copper are preferably used as an electrically conductive material for the formation of the aforementioned electrically conductive pattern. In addition, alloys of at least one of these metals are preferably used. The electrically conductive pattern such as the electrical interconnect lines Y has a thickness preferably in the range of 3 to 30 μm (more preferably in the range of 3 to 18 μm). The coverlay 36 formed on the electrically conductive pattern has a thickness preferably in the range of 1 to 50 μm (more preferably in the range of 1 to 25 μm), for example, in consideration of the insulation protection and even reinforcement of the electrical interconnect lines Y and the like.

Then, an electroplated layer made of nickel, gold, or the like is formed on portions which are exposed from the coverlay 36 and become the various pads 34a and 34b and the connecting terminals 35, whereby the electric circuit part E is obtained (with reference to FIG. 4).

(2) Patterning of Metal Reinforcement Layer 37

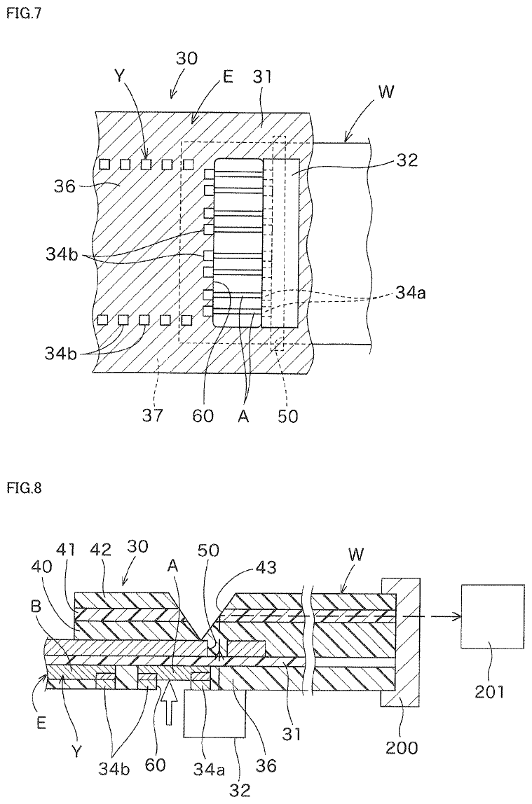

Next, an etching process (dry film resist lamination, exposure, development, etching, dry film resist removal, and the like) is performed on the metal reinforcement layer 37 on the opposite side of the insulative layer 31 from the electric circuit part. E to remove an unnecessary portion, thereby forming a predetermined pattern shape. This provides necessary openings and notches such as the through hole 50 for optical coupling to the optical element 32 (with reference to FIG. 1), as shown in FIG. 5.

(3) Formation of Optical Waveguide W

Next, the insulative layer 31 with the electric circuit part E and the metal reinforcement layer 37 is turned upside down, so that the metal reinforcement layer 37 faces upward. Then, the under cladding layer 40, the core 41, and the over cladding layer 42 are formed in a stacked manner by a known method on a surface of the insulative layer 31 on the side where the metal reinforcement layer 37 is formed, with each layer patterned into a predetermined pattern as required, whereby the optical waveguide W is obtained.

While the optical coupling to the optical element 32 to be provided on the electric circuit part E side of the insulative layer 31 is assumed, a predetermined portion of the optical waveguide W is formed into an inclined surface inclined at 45 degrees with respect to the longitudinal direction of the core 41 by dicing, laser machining, cutting, or the like to provide the light reflecting portion 43. In this manner, the opto-electric hybrid board 30 shown in FIG. 1 is obtained. An optical connector for connection to other electrical interconnect members is attached to a tip side not shown opposite the side facing the electric circuit part E as seen in the longitudinal direction of the optical waveguide W.

In the opto-electric hybrid board 30, the coverlay 36 for covering the surface of the electric circuit part E is not formed in the area overlapping the interconnect line portions A connecting the pads 34a for mounting the optical element 32 and the pads 34b for the optical element driving device 33, but this area is the opening 60. For this reason, the interconnect line portions A are exposed through the opening 60. Thus, although having a simple configuration such that only the opening 60 is provided in a portion of the coverlay 36 covering the electric circuit part E, the opto-electric hybrid board 30 allows a burn-in test to be conducted reliably with high accuracy by causing a probe pin to conduct through this portion.

There is no need to perform a special process in order to obtain the opto-electric hybrid board 30. The opto-electric hybrid board 30 is obtained easily at low costs. This allows a wide use of the opto-electric hybrid board 30 for consumer applications. Also, there is no need to incorporate an electric circuit for the burn-in test. This eliminates the need to provide extra space in the opto-electric hybrid board 30.

In addition, when the opening 60 is provided in the coverlay 36 covering the electric circuit part E as mentioned above to expose the interconnect line portions A connecting the optical element 32 and the optical element driving device 33, the capacitance of the optical element 32 is smaller than that obtained when the opening 60 is not provided. This is advantageous in that the opto-electric hybrid board 30 can be used in higher frequency bands.

(4) Formation of Optical Communication Module

The opto-electric hybrid board 30 thus obtained may be connected to a wiring board 20 for use in various electric and electronic devices, for example, as shown in FIG. 6 and used as an optical communication module board, in addition to being used alone. Then, necessary devices are mounted on this board, whereby an optical communication module is provided. The wiring board 20 is configured, for example, such that an electric circuit including the electrical interconnect lines X, connecting terminals 22, and the like is provided on a surface of a substrate (a rigid or flexible substrate) 21 and such that a portion of a surface of the electric circuit where insulation is required is covered with an insulative layer 23. The connection of the opto-electric hybrid board 30 to the wiring board 20 is generally made by facing the connecting terminals 35 and 22 thereof in vertically stacked relation and then electrically connecting the faced connecting terminals 35 and 22 with solder bumps or the like.

The aforementioned optical communication module, which is low-cost, compact, and easy to conduct the burn-in test on the optical element mounted thereon, is inspectable for initial failure and is excellent in quality reliability.

In particular, when the aforementioned optical communication module is used after being connected to a predetermined electric and electronic device and installed in a building or incorporated inside a device, the aforementioned burn-in test is easily conducted prior to the installation or incorporation, which is very useful.

[Optical Element Inspection Method]

An optical element inspection method in the aforementioned optical communication module is performed, for example, in the following manner. First, the optical element (light-emitting element: VCSEL) 32 is mounted on the opto-electric hybrid board 30 of the optical communication module, as shown in FIG. 7. Then, the burn-in test is easily conducted by placing the optical communication module in a constant temperature bath set at a predetermined temperature, connecting a probe pin to the interconnect line portions A exposed through the opening 60 provided in the coverlay 36 (shaded portion) in the vicinity of the optical element 32, and causing a larger current than during actual use to flow. Then, the optical communication module taken out of the aforementioned constant temperature bath is inspected for any defect in the optical element 32.

The aforementioned optical element inspection method will be described in further detail with reference to FIG. 8 schematically showing a vertical section of the opto-electric hybrid board 30. For exposure of the optical element 32 to harsh conditions, the optical communication module is placed in a constant temperature bath set at a predetermined high temperature (e.g., 60 to 120° C.), and a probe pin is connected to the interconnect line portions A exposed through the opening 60 of the coverlay 36 on the surface of the opto-electric hybrid board 30 on the side where the electric circuit part E is formed, as indicated by a hollow arrow. Then, a large current is caused to flow from the interconnect line portions A to the optical element 32. This makes a test as to whether light is emitted from the optical element 32 without any trouble even under harsh conditions or not. At this time, an optical signal propagates in the optical waveguide W as indicated by broken lines.

Next, the optical communication module is taken out of the constant temperature bath. A power meter 201 (e.g., an optical power meter 8250A and an optical sensor 82321B available from ADC Corporation) is connected through an optical connector 200 to the other end of the optical waveguide W of the aforementioned optical communication module. At the same time, a current is applied to the interconnect line portions A exposed through the opening 60 of the coverlay 36 of the opto-electric hybrid board 30 to emit light from the optical element 32, and the optical signal propagated from the optical waveguide W is measured. The inspection of the optical element 32 for initial failure is performed by whether this optical signal indicates a measured value within proper specifications or not.

In the aforementioned burn-in test, the value of current applied to the interconnect line portions A for burn-in is preferably set to 1.5 to 3 times the value of current applied to the optical element 32 during actual use. If the current value is smaller than the aforementioned range, there is a danger that the optical element 32 cannot be correctly inspected for initial failure in a short time. On the other hand, if the current value is greater than the aforementioned range, there is a danger that the current value exceeds an allowable current value that the optical element 32 originally has, so that even the normal optical element 32 is destroyed.

In the aforementioned example, the burn-in test is conducted in the stage where only the optical element 32 is mounted. However, the burn-in test may be conducted in the stage where both the optical element 32 and the optical element driving device 33 are mounted, using the space therebetween, as shown in FIG. 9. A method for the burn-in test is the same as in the example shown in FIG. 8, and the description thereof will be dispensed with.

In the aforementioned example, a burn-in apparatus is used to place the optical communication module under high temperature conditions, and the interconnect line portions A are used to apply a large current to the optical element 32. Thereafter, the optical communication module is taken out of the burn-in apparatus, and the judgment test for evaluation of the quality of the optical element 32 is conducted. However, the burn-in test need not necessarily be conducted in such two steps. For example, while a large current is cause to flow from the interconnect line portions A, an optical signal propagated through the tip of the optical waveguide W may be converted into an electric signal by a light-receiving element (e.g., a PD) connected thereto, so that the optical element 32 is inspected for initial failure by means of the measured value of the electric signal.

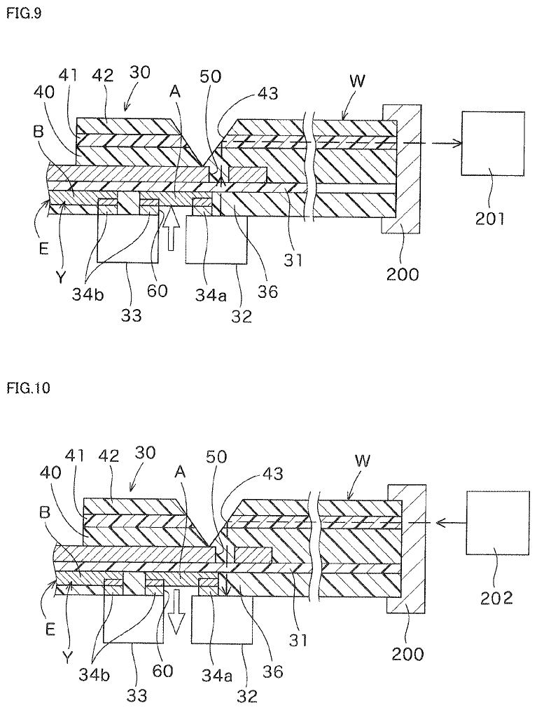

In these examples, the burn-in test is conducted by applying a current to the optical element 32. However, another method as shown in FIG. 10 may be performed, for example, in which a light source 202 is connected through the optical connector 200 to the tip of the optical waveguide W in the aforementioned optical communication module to propagate an optical signal in the optical waveguide W as indicated by broken lines, and the optical element (light-receiving element) 32 changes the optical signal to an electric signal, whereby the quality thereof is inspected. Specifically, the electrical signal converted in the optical element 32 is measured by an electrometer (e.g., electrometer 5350 available from ADC Corporation) connected to the interconnect line portions A exposed through the opening 60, whereby the optical element 32 is inspected for initial failure.

Another method of checking the quality of the optical element (light-receiving element) 32 is as follows. For example, instead of propagating the optical signal to the optical element 32 as mentioned above, a reverse bias voltage is applied to the optical element 32 using the interconnect line portions A exposed through the opening 60 of the coverlay 36 as a terminal, so that a current (dark current) generated in the optical element 32 is measured. The quality of the optical element 32 is inspected assuming that there is no problem with the quality of the optical element 32 if this current does not exceed a predetermined level. The application of the aforementioned voltage is generally performed, with this optical communication module placed in a constant temperature bath (e.g., set at 60 to 120° C.) for a predetermined period of time.

In the present disclosure, the opening 60 of the coverlay 36 is preferably set so that an opening dimension [indicated by J in FIG. 2] of the opening 60 as measured in the longitudinal direction of the interconnect line portions A is 0.5 to 1.2 when a longitudinal dimension [indicated by H in FIG. 2] of the interconnect line portions A is 1. If the opening dimension J of the opening 60 as measured in the longitudinal direction of the interconnect line portions A is too smaller than the aforementioned range, it is difficult to connect to the tip of the probe pin for the burn-in test, which is not preferable. The greater the opening 60 is, the smaller the capacitance of the mounted optical element 32 tends to be. In consideration of such a tendency, the ratio of J to H is preferably set especially to 0.8 to 1 within the aforementioned range.

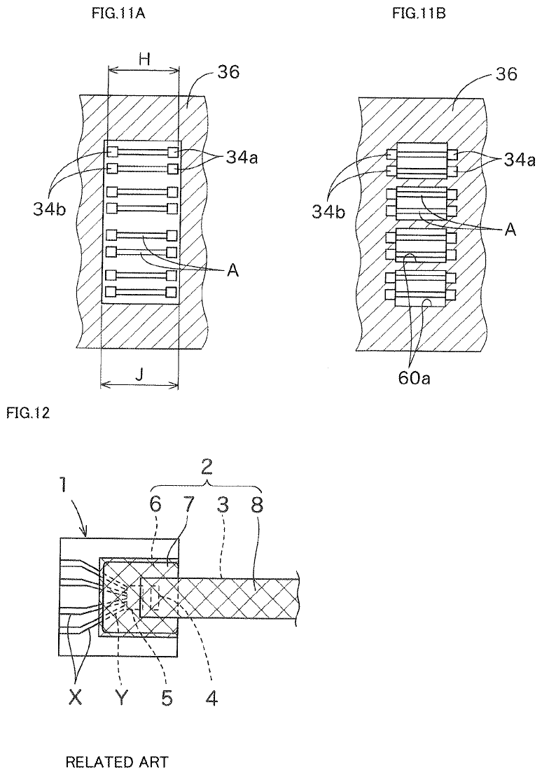

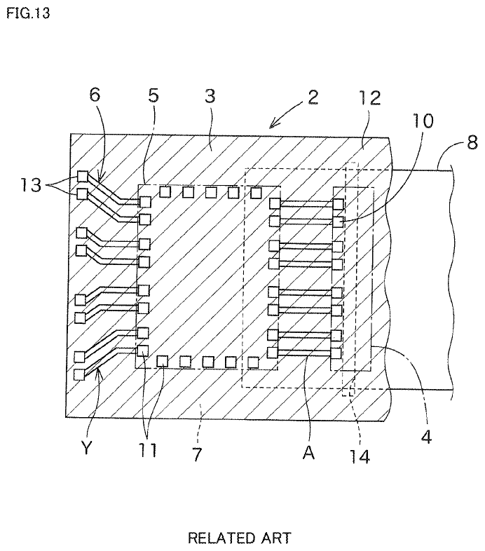

The opening 60 of the coverlay 36 need not be provided only in the area overlapping the interconnect line portions A. For example, as shown in FIG. 11A, the opening may include the area overlapping the interconnect line portions A and areas between the pads 34a and between the pads 34b on both sides thereof.

In addition, the opening 60 need not be a single opening. For example, as shown in FIG. 11B, individual openings 60a (four openings 60a in this example) may be provided for respective channels. This configuration, in which portions of the coverlay 36 remain as partitions between the channels, is inferior to the aforementioned example in terms of the effect of capacitance removal, but is advantageous in that the edges of the openings 60a are less prone to be peeled off. Further, the effect of electrical insulation between the channels is improved because the individual opening is formed for each of the channels.

In the aforementioned example, the types of signals flowing in the interconnect line portions A and the interconnect line portions B are not particularly limited, and appropriate signals are selected in accordance with the types of the optical element 32 and various devices to be connected. Examples of the signal types include single-ended signals, differential signals, and coplanar signals.

Next, examples will be described. It should be noted that the present disclosure is not limited to the following examples.

### EXAMPLES

An optical communication module board having a configuration shown in FIG. 6 was produced in accordance with the procedure described in the aforementioned embodiment. The materials and thicknesses of main components are as follows.

[Opto-Electric Hybrid Board 30]
Insulative layer 31: polyimide; 15 μm in thickness
Electrical interconnect lines Y (including the interconnect line portions A and B) of an electric circuit part: copper; 10 μm in thickness (with pads and terminal gold plating)
Coverlay 36: polyimide; 5 μm in thickness (as measured from a surface of the insulative layer 31)
Metal reinforcement layer 37: stainless steel; 20 μm in thickness
Under cladding layer 40: photo-curable epoxy resin composition; 30 μm in thickness
Core 41: photo-curable epoxy resin composition; 40 μm in thickness
Over cladding layer 42: photo-curable epoxy resin composition; 70 μm in thickness (as measured from a surface of the under cladding layer 40)

[Wiring Board 20]
Substrate 21: glass epoxy resin (FR4, 4-layer through plate); 1.6 mm in total thickness
Electrical interconnect lines X: copper; 35 μm in thickness (with pads and terminal gold plating)
Optical element 32: VCSEL (product designation: APA4401040001 available from II-VI Laser Enterprise GmbH)
Optical element driving device 33: IC (product designation: SL82817 available from Silicon Line GmbH)

[Preparation of Simulated Defective Product]

To simulate the occurrence of initial failure in the VCSEL in an optical communication module manufacturing process, the following processing was performed on the VCSEL prior to mounting. First, an ESD simulator ESS-6002 available from Noise Laboratory Co., Ltd. was used to apply a voltage of Human Body Model (HBM)+200 V, which exceeded the ESD withstanding voltage of the VCSEL, to the VCSEL three times, and then apply a voltage of −200 V thereto three times. Then, this VCSEL was mounted on the opto-electric hybrid board 30, as shown in FIG. 8.

### Example 1

Of 100 pieces to be inspected, 6 pieces are optical communication modules each mounted with the VCSEL subjected to the aforementioned ESD test, and the remaining 94 pieces are modules each mounted with a normal VCSEL not subjected to the ESD test. These 100 optical communication modules were placed in a constant temperature bath at 85° C., and a direct current of 10 mA was passed continuously for 100 hours through the VCSELs from the interconnect line portions A exposed through the opening 60 of the opto-electric hybrid board 30.

Thereafter, a DC stabilization power supply PMX35-1A available from Kikusui Electronics Corp. was connected to the interconnect line portions A exposed through the opening 60 of the opto-electric hybrid board 30 in each of the 100 modules to be inspected which were taken out of the constant temperature bath. While a current of 6 mA was passed, an optical signal converted in the optical element 32 in each of the 100 modules was measured with a power meter coupled to the optical waveguide W. A module having an optical output out of specifications is judged as defective.

Of the 100 modules, the 6 modules each mounted with the VCSEL subjected to the ESD test had optical outputs that were out of specifications, as a result of the aforementioned inspection. On the other hand, the remaining 94 modules each mounted with the normal VCSEL had optical outputs that were within specifications.

### Example 2

In the aforementioned optical communication module, the VCSEL and the optical element driving device 33 were mounted on the opto-electric hybrid board 30, as shown in FIG. 9. Thereafter, the inspection was performed in the same manner as in Example 1 described above. Of 100 pieces to be inspected, 6 pieces are modules each mounted with the VCSEL subjected to the aforementioned ESD test, as in Example 1 described above.

Of the 100 modules, the 6 modules each mounted with the VCSEL subjected to the ESD test had optical outputs that were out of specifications, as a result of the aforementioned inspection. On the other hand, the remaining 94 modules each mounted with the normal VCSEL had optical outputs that were within specifications.

These results show that the optical element inspection method of the present disclosure is capable of easily and accurately inspecting optical elements for initial failure.

Although specific forms in the present disclosure have been described in the aforementioned examples, the aforementioned examples should be considered as merely illustrative and not restrictive. It is contemplated that various modifications evident to those skilled in the art could be made without departing from the scope of the present disclosure.

The opto-electric hybrid board according to the present disclosure, the optical communication module using the same, and the optical element inspection method in the optical communication module, which are capable of easily inspecting the optical element for initial failure, are widely used for the provision of an optical communication module excellent in quality reliability.

### REFERENCE SIGNS LIST

30 Opto-electric hybrid board
31 Insulative layer
32 Optical element
33 Optical element driving device
34a, 34b Pads
36 Coverlay
60 Opening
A Interconnect line portions
E Electric circuit part.
W Optical waveguide
Y Electrical interconnect lines

1. An opto-electric hybrid board for use in an optical communication module, comprising:
an insulative layer;
an electric circuit part provided on a first surface side of the insulative layer, the electric circuit part including a pad for mounting an optical element, a pad for an optical element driving device, and an electrical interconnect line Y including an interconnect line portion A connecting the pads;
a coverlay covering the electric circuit part; and
an optical waveguide provided on a second surface side of the insulative layer;
wherein the coverlay has an opening in an area overlapping the interconnect line portion A, and the interconnect line portion A exposed through the opening is used as a terminal for a burn-in test of an optical element.

2. The opto-electric hybrid board according to claim 1,
wherein an opening dimension J of the opening of the coverlay as measured in a longitudinal direction of the interconnect line portion A is set to 0.5 to 1.2 when a longitudinal dimension H of the interconnect line portion A including the pads on opposite sides is 1.

3. An optical communication module comprising:
an opto-electric hybrid board as recited in claim 1; and
a wiring board electrically connected to the opto-electric hybrid board,
wherein at least an optical element is mounted on the opto-electric hybrid board and is optically coupled to the optical waveguide of the opto-electric hybrid board, and
wherein the interconnect line portion A exposed through the opening provided in the coverlay of the opto-electric hybrid board is used as a terminal for a burn-in test of the optical element.

4. The optical communication module according to claim 3,
the optical communication module being for consumer use.

5. An optical element inspection method,
comprising a step of obtaining the optical communication module as recited in claim 3, wherein at least the optical element is mounted; a current is passed through the optical element with the use of the interconnect line portion A exposed through the opening of the covet-lay as a terminal, with the optical element optically coupled to the optical waveguide of the opto-electric hybrid board; the current is converted into an optical signal by the optical element; the optical signal is outputted through the optical waveguide; and the outputted optical signal is measured, whereby the quality of the optical element is inspected.

6. The optical element inspection method according to claim 5,
wherein a current having a current value 1.5 to 3 times a current value for driving the optical element during actual use is passed through the optical element, whereby the inspection is conducted.

7. An optical element inspection method,
comprising a step of obtaining the optical communication module as recited in claim 3, wherein at least the optical element is mounted; a reverse bias voltage is applied to the optical element with the use of the interconnect line portion A exposed through the opening of the coverlay as a terminal, with the optical element optically coupled to the optical waveguide of the opto-electric hybrid board; and a current generated in the optical element is measured, whereby the quality of the optical element is inspected.

8. An optical element inspection method,
comprising a step of obtaining the optical communication module as recited in claim 3, wherein at least the optical element is mounted; an optical signal is transmitted through the optical waveguide to the optical element, with the optical element optically coupled to the optical waveguide of the opto-electric hybrid board; the optical signal is converted into an electric signal in the optical element; and the electric signal is measured with the use of the interconnect line portion A exposed through the opening of the coverlay as a terminal, whereby the quality of the optical element is inspected.
